(19) United States
(12) Patent Application Publication
(10) Pub. No.: US 2022/0320069 A1
(43) Pub. Date: Oct. 6, 2022

(54) ELECTROSTATIC DISCHARGE PROTECTION CIRCUIT

(71) Applicant: Changxin Memory Technologies, Inc., Hefei (CN)

(72) Inventor: Zhan YING, HEFEI (CN)

(21) Appl. No.: 17/752,258

(22) Filed: May 24, 2022

Related U.S. Application Data
(63) Continuation of application No. PCT/CN2021/113125, filed on Aug. 17, 2021.

(30) Foreign Application Priority Data
Apr. 1, 2021 (CN) 202110355596.7

(51) Int. Cl. H01L 27/02; H02H 9/04

(52) U.S. Cl. CPC H01L 27/027; H02H 9/046

(57) ABSTRACT

This application provides an electrostatic discharge protection circuit, disposed between a first pad and a second pad of a circuit. The electrostatic discharge protection circuit includes: a main discharge transistor and an auxiliary discharge transistor, both configured to be conductive after an electrostatic pulse caused by electrostatic charges is detected on the first pad to discharge the electrostatic charges to the second pad. Conduction time of the main discharge transistor is prior to conduction time of the auxiliary discharge transistor. An amount of the electrostatic charges discharged by the main discharge transistor is greater than an amount of the electrostatic charges discharged by the auxiliary discharge transistor. The circuit provided in this application can prolong bleeding of the electrostatic charges time and has a sufficient electrostatic discharge capability.

### CROSS REFERENCE TO RELATED APPLICATIONS

This application is a continuation application of International Patent Application No.: PCT/CN2021/113125, filed on Aug. 17, 2021, which claims priority to Chinese Patent Application No.: 202110355596.7 filed with the Patent Office of China on Apr. 1, 2021, titled “ELECTROSTATIC DISCHARGE PROTECTION CIRCUIT”, the entirety of the above applications are incorporated herein by their reference.

### TECHNICAL FIELD

This application relates to, but is not limited to, an electrostatic discharge protection circuit.

### BACKGROUND

Static electricity is everywhere. Absent an electrostatic discharge protection circuit to protect a semiconductor chip, the semiconductor chip may be damaged by static electricity introduced to the semiconductor chip, thereby potentially causing the semiconductor chip to be non-functional.

Therefore, a semiconductor chip is usually provided with an electrostatic discharge protection circuit, which is configured to discharge electrostatic electricity to avoid catastrophic failures to the semiconductor chip.

### SUMMARY

An embodiment of this application provides an electrostatic discharge protection circuit (e.g., an ESD circuit), disposed between a first pad and a second pad of an integrated circuit, and includes: a main discharge transistor and an auxiliary discharge transistor, both configured to be conductive after an electrostatic pulse caused by electrostatic charges is detected on the first pad. The main discharge transistor and an auxiliary discharge transistor discharge the electrostatic charges from the first pad to the second pad, where conduction time of the main discharge transistor is prior to conduction time of the auxiliary transistor, and an amount of the electrostatic charges discharged by the main discharge transistor is greater than an amount of the electrostatic charges discharged by the auxiliary discharge transistor.

### BRIEF DESCRIPTION OF THE ACCOMPANYING DRAWINGS

The accompanying drawings are incorporated in and constitute a part of the specification, illustrate embodiments consistent with this application, and together with the description serve to explain the principles of this application.

FIG. 1 illustrates a schematic diagram of an electrostatic discharge protection circuit, according to an embodiment of this application.

FIG. 2 illustrates a schematic diagram of an electrostatic discharge protection circuit, according to an embodiment of this application.

FIG. 3 illustrates a schematic diagram of an electrostatic discharge protection circuit, according to an embodiment of this application.

FIG. 4 illustrates a circuit diagram of an electrostatic discharge protection circuit of an internal circuit, according to an embodiment of this application.

FIG. 5 illustrates a circuit diagram of an electrostatic discharge protection circuit of an internal circuit, according to an embodiment of this application.

FIG. 6 illustrates a circuit diagram of an electrostatic discharge protection circuit of an internal circuit, according to an embodiment of this application.

FIG. 7 illustrates a circuit diagram of an electrostatic discharge protection circuit of an internal circuit, according to an embodiment of this application.

Specific embodiments of this application have been explicitly shown by the above accompanying drawings and will be described in more detail later. These accompanying drawings and literal descriptions are not intended in any way to limit the scope of concepts of this application but, rather, to illustrate the concepts for those skilled in the art by reference to specific embodiments.

### DETAILED DESCRIPTION OF THE EMBODIMENTS

Exemplary embodiments, examples of which are shown in the accompanying drawings, will be explained in detail herein. When the following description relates to the accompanying drawings, the same numerals in different accompanying drawings denote the same or similar elements unless otherwise indicated. The implementations described in the following exemplary embodiments are not representative of all implementations consistent with this application. Instead, they are only examples of devices and methods consistent with some aspects of this application as detailed in the appended claims.

Static electricity is everywhere. Absent an electrostatic discharge (ESD) protection circuit to protect a chip (e.g., a semiconductor device), the chip may be damaged by static electricity introduced to the chip, thereby potentially causing the chip to be non-functional. For example, when a person touches a pin of a chip, voltage at the pin can reach several hundred or even thousands of volts, which can cause an electrostatic discharge and potentially damage the chip. As another example, when a device (e.g., a semiconductor fabrication robotic arm) touches a pin of a chip, voltage at the pin touched by the device can reach several hundred of volts, which can cause an electrostatic discharge and potentially damage the chip.

To ensure safety of chips, each chip includes an electrostatic discharge protection circuit. In general, types of electrostatic discharge protection circuits can vary according to functions of pins for which the electrostatic discharge protection circuits are designed to protect. For example, electrostatic discharge protection circuits to protect power supply pins of chips can be different from electrostatic discharge protection circuits to protect I/O pins of chips.

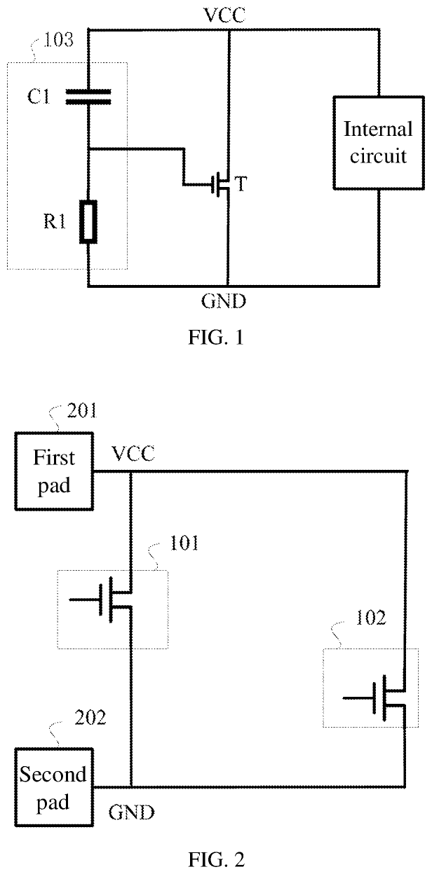

FIG. 1 illustrates a schematic diagram of an electrostatic discharge protection circuit, according to an embodiment of this application. The electrostatic discharge protection circuit is disposed between a power supply end VCC and a grounding end GND. The electrostatic discharge protection circuit includes a monitoring unit 103 and a discharge transistor T. The monitoring unit 103 includes a monitoring capacitor C1 and a monitoring resistor R1. The monitoring capacitor C1 is connected or coupled to the monitoring capacitor R1 in series. One end of the monitoring unit 103 is connected or coupled to the power supply end VCC while the other end of the monitoring unit 103 is connected to the grounding end GND.

Because the discharge transistor T is directly connected or coupled to the monitoring capacitor C1, conduction speed of the discharge transistor T can be very fast. However, to ensure that the discharge transistor T becomes conductive (e.g., turned on) when an electrostatic pulse caused by an electrostatic discharge event (an ESD event) is detected, the monitoring resistor R1 is usually set to be tens of thousands of ohms. In this way, the discharge transistor T can be quickly turned off when electrostatic charge at a gate of the discharge transistor T discharges through the monitoring resistor R1. As such, the discharge transistor T is configured to be conductive for only a short time. However, there is a risk that, within this short time at which the discharge transistor T is conductive, electrostatic charges introduced to the power supply end VCC may not completely be discharged to the grounding end GND, thereby may cause potential damage to an internal circuit protected by the electrostatic discharge protection circuit.

FIG. 2 illustrates a schematic diagram of an electrostatic discharge protection circuit, according to an embodiment of this application. The electrostatic discharge protection circuit shown in FIG. 2 can be configured to protect a power supply pin of a semiconductor device (not shown). As shown in FIG. 2, the electrostatic discharge protection circuit is disposed between a first pad 201 and a second pad 202 of the semiconductor chip. The first pad 201 may be a power supply pad of the semiconductor chip and the second pad 202 may be a grounding pad of the semiconductor chip.

The electrostatic discharge protection circuit includes a main discharge transistor 101 and an auxiliary discharge transistor 102. The main discharge transistor 101 is configured to be conductive after an electrostatic pulse caused by an electrostatic discharge event is detected at the first pad 201. The main discharge transistor 101 can discharge (e.g., bleed) electrostatic charges accumulated on the first pad 201 (e.g., VCC) to the second pad 202 (e.g., GND). The auxiliary discharge transistor 102 is configured to be conductive after the electrostatic pulse is detected, and subsequent to conduction of the main discharge transistor 101, to further bleed the electrostatic charges from the first pad 201 to the second pad 202.

Conduction time of the main discharge transistor 101 is prior to conduction time of the auxiliary discharge transistor 102. That is, after the electrostatic pulse is detected, the main discharge transistor 101 becomes conductive first, to discharge the electrostatic charges from the first pad 201 to the second pad 202. The auxiliary discharge transistor 102 becomes conductive shortly thereafter, to further discharge the electrostatic charges. The main discharge transistor 101 and the auxiliary discharge transistor 102 both become conductive to discharge the electrostatic charges from the first pad 201 to the second pad 202 together. After a period of time, the main discharge transistor 101 is gradually turned off and, therefore, no longer can discharge the electrostatic charges. At this time, the auxiliary discharge transistor 102 is still conductive and can continuously discharge remaining electrostatic charges from the first pad 201 to the second pad 202.

A discharge capacity of the main discharge transistor 101 is higher than a discharge capacity of the auxiliary discharge transistor 102. That is, an amount of electrostatic charges discharged by the main discharge transistor 101 is greater than an amount of electrostatic charges discharged by the auxiliary discharge transistor 102. When an electrostatic pulse is detected on the first pad 201, the main discharge transistor 101 become conductive first, and most of electrostatic charges are rapidly discharged through the main discharge transistor 101 to GND. In this way, voltage of the first pad 201 does not rapidly rise due to accumulation of electrostatic charges on the first pad 201, thereby protecting the semiconductor chip from damage from an electrostatic discharge event.

In the above-mentioned technical solution, the main discharge transistor 101 becomes conductive before the auxiliary discharge transistor 102 becomes conductive, and an amount of electrostatic charges discharged through the main discharge transistor 101 is greater than an amount of electrostatic charges discharged through the auxiliary discharge transistor 102. In this way, when an electrostatic pulse is detected, the main discharge transistor 101 rapidly discharges electrostatic charges, to ensure voltage of the first pad 201 does not rapidly rise due to accumulation of electrostatic charges on the first pad 201, thereby protecting the semiconductor chip. In addition, when the main discharge transistor 101 is turned off, the auxiliary discharge transistor 102 is still conductive and may continuously discharge remaining electrostatic charges, thereby prolonging discharge time and improving discharge capability of the electrostatic discharge protection circuit.

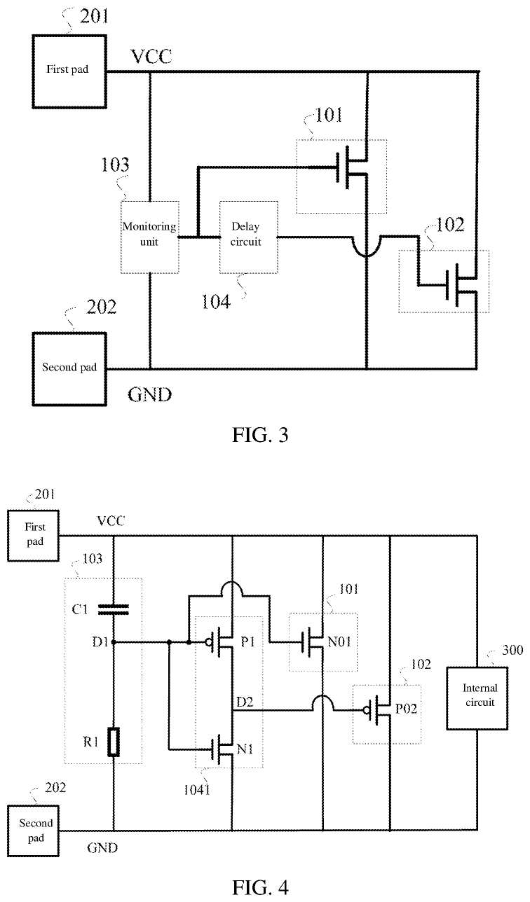

FIG. 3 illustrates a schematic diagram of an electrostatic discharge protection circuit, according to an embodiment of this application. As shown in FIG. 3, the electrostatic discharge protection circuit is disposed between a first pad 201 and a second pad 202. The electrostatic discharge protection circuit includes a main discharge transistor 101, an auxiliary discharge transistor 102, a monitoring unit 103, and a delay circuit 104.

The monitoring unit 103 is provided with an output end, and the main discharge transistor 101 is provided with a control end, a first end, and a second end. The output end of the monitoring unit 103 is connected or coupled to the control end of the main discharge transistor 101. The first end of the main discharge transistor 101 is connected or coupled to the first pad 201 and the second end of the main discharge transistor 101 is connected or coupled to the second pad 202. The delay circuit 104 is provided with an input end and an output end. The auxiliary discharge transistor 102 is provided with a control end, a first end, and a second end. The control end of the main discharge transistor 101 is further connected or coupled to the input end of the delay circuit 104, and the output end of the delay circuit 104 is connected or coupled to the control end of the auxiliary discharge transistor 102. The first end of the auxiliary discharge transistor 102 is connected or coupled to the first pad 201, and the second end of the auxiliary discharge transistor 102 is connected or coupled to the second pad 202.

The monitoring unit 103 is configured to monitor an electrostatic pulse caused by electrostatic charges accumulated on the first pad 201 and output a first control signal when the electrostatic pulse is detected on the first pad 201. The first control signal causes the main discharge transistor 101 to become conductive and discharge the electrostatic charges from the first pad 201 to the second pad 202. The delay circuit 104 is configured to delay the first control signal outputted by the monitoring unit 103 and convert the first control signal into a second control signal that causes the auxiliary discharge transistor 102 to become conductive. In this way, the auxiliary discharge transistor 102 is configured to be conductive after some time delay after the main discharge transistor 101 becomes conductive and discharges the electrostatic charges together with the main discharge transistor 101. After the electrostatic charges are discharged for a period of time, the first control signal at the output end of the monitoring unit 103 is switched, so that the main discharge transistor 101 is turned off and no longer discharges the electrostatic charges. At this time, the second control signal outputted by the delay circuit 104 is delayed for a period of time before the second control signal is switched. This allows the auxiliary discharge transistor 102 to remain conductive and continuously discharges the electrostatic charges from the first pad 201 to the second pad 202 while the main discharge transistor 101 ceases to be conductive. After the second control signal outputted by the delay circuit is switched, the auxiliary discharge transistor 102 is gradually turned off. Delay time of the delay circuit 104 may be set according to actual process conditions. For example, the delay time of the delay circuit 104 can be set to picoseconds or nanoseconds.

In an embodiment, a size (i.e., dimensions) of the main discharge transistor 101 is greater than a size of the auxiliary discharge transistor 102. That is, the main discharge transistor 101 has a discharge capacity higher than a discharge capacity of the auxiliary discharge transistor 102. As such, the main discharge transistor 101 discharges a larger portion of electrostatic charges. When an electrostatic pulse is detected, the monitoring unit 103 causes the main discharge transistor 101 to be conductive and the main discharge transistor 101 discharges electrostatic charges from the first pad 201 to the second pad 202 with a relatively large discharge current, so that voltage on the first pad 201 does not rise excessively fast due to accumulation of electrostatic charges. The auxiliary discharge transistor 102 continuously discharges remaining electrostatic charges after the main discharge transistor 101 is turned off, thereby improving a discharge capability of the electrostatic discharge protection circuit.

FIG. 4 illustrates a circuit diagram of an electrostatic discharge protection circuit of an internal circuit 300, accord to an embodiment of this application. The schematic shown in FIG. 4 is same as the schematic shown in FIG. 3. The only difference is that circuitries of the monitoring unit 103 and the delay circuit 104 are shown in detail. As shown in FIG. 4, the main discharge transistor 101 is an N-type transistor 101 and the auxiliary discharge transistor 102 is a P-type transistor P02. The monitoring unit 103 includes a monitoring capacitor C1 and a monitoring resistor R1 connected or coupled in series. The monitoring capacitor C1 is provided with a first end and a second end, and the monitoring resistor R1 is also provided with a first end and a second end. The first end of the monitoring capacitor C1 is connected or coupled to the first pad 201, and the second end of the monitoring resistor R1 is connected or coupled to the second pad 202. The first pad 201 is a power supply pad of the internal circuit 300, and the second pad 202 is a grounding pad of the internal circuit 300. The first end of the monitoring resistor R1 is connected or coupled to the second end of the monitoring capacitor C1, and is the output end of the monitoring unit 103.

The delay circuit 104 includes a first inverter 1041. An input end of the first inverter 1041 corresponds to the input end of the delay circuit 104, and an output end of the first inverter 1041 corresponds to the output end of the delay circuit 104. The first inverter 1041 includes a first driving transistor P1 and a second driving transistor N1. The first driving transistor P1 is a P-type transistor, and the second driving transistor N1 is an N-type transistor.

A source of the first driving transistor P1 is connected or coupled to the first pad 201, and a source of the second driving transistor N1 is connected or coupled to the second pad 202. A drain of the first driving transistor P1 is connected or coupled to a drain of the second driving transistor N1, and is the output end of the first inverter 1041. A gate of the first driving transistor P1 is connected or coupled to a gate of the second driving transistor N1, and is the input end of the first inverter 1041.

A gate of the main discharge transistor 101 is connected or coupled to the second end of the monitoring capacitor C1. The gate of the first driving transistor P1 and the gate of the second driving transistor N1 are also connected or coupled to the second end of the monitoring capacitor C1, The drain of the first driving transistor P1 and the drain of the second driving transistor N1 are connected or coupled to a gate of the auxiliary discharge transistor 102.

In an embodiment, the auxiliary discharge transistor 102 and the P-type transistor of the first inverter 1041 are located in the same N-type well on a substrate. That is, the auxiliary discharge transistor 102 and the first driving transistor P1 are arranged in the same N-type well on the substrate. In this way, a layout of the electrostatic discharge protection circuit can be optimized and reduce an area of the layout.

In an embodiment, the main discharge transistor 101 and the second driving transistor N1 are arranged in separate P-type wells on a substrate, and a discharge current of the main discharge transistor 101 is larger than a discharge current of the second driving transistor N1. The main discharge transistor 101 is arranged separate from the second driving transistor N1 to avoid mutual influence between the main discharge transistor 101 and the second driving transistor N1, thereby ensuring discharge current performance of the main discharge transistor 101.

In an embodiment, the auxiliary discharge transistor 102 and the first driving transistor P1 may be arranged adjacent to the main discharge transistor 101 to facilitate layout design.

In an embodiment, the auxiliary discharge transistor 102 and the P-type transistor of the first inverter 1041 are located in different N-type wells on a substrate. That is, the auxiliary discharge transistor 102 and the first driving transistor P1 are arranged in different N-type wells on the substrate. The auxiliary discharge transistor 102 is configured to discharge electrostatic charges, the first driving transistor P1 is configured to drive the auxiliary discharge transistor 102 to become conductive, current of the auxiliary discharge transistor 102 may be larger than current of the first driving transistor P1, a size (e.g., dimensions) of the auxiliary discharge transistor 102 is also larger than a size of the first driving transistor P1, and the auxiliary discharge transistor 102 and the first driving transistor P1 are located in different N-type wells on the substrate, thereby avoiding mutual influence between the auxiliary discharge transistor 102 and the first driving transistor P1, and ensuring the discharge current performance of the auxiliary discharge transistor 102.

The working principle of the electrostatic discharge protection circuit of FIG. 4 is described below with reference to FIG. 4:

When an electrostatic pulse is detected on the first pad 201, for example, voltage of the power supply VCC rises from 0 V to 1 V in 1 ns (after Fourier decomposition, a fundamental frequency can be considered to be approximately 1 Ghz). Because an equivalent impedance of the monitoring capacitor C1 to a high frequency signal is 1/(2*π*f*C1), a smaller rise time indicates a higher signal frequency and a smaller equivalent impedance of the monitoring capacitor C1. Voltage at node D1 is approximately same as VCC. Under this scenario, the main discharge transistor 101 becomes conductive. The second driving transistor N1 also becomes conductive. After the second driving transistor N1 becomes conductive, voltage at node D2 is pulled down to GND. That is, voltage at node D2 is not pulled down to GND until after a delay in conduction time of the second driving transistor N1. The first inverter 1041 outputs a low-level signal, and the auxiliary discharge transistor 102 becomes conductive in response to the low-level signal. Because the main discharge transistor 101 is directly connected or coupled to the monitoring capacitor C1, conduction speed of the main discharge transistor 101 is very fast, and the main discharge transistor 101 can quickly discharge electrostatic charges accumulated on the first pad 201. Conduction of the main discharge transistor 101 and conduction of the auxiliary discharge transistor 102 may slow down the continuous rise of voltage of the power supply VCC to a certain extent, but because conduction capacities or discharge speeds of the main discharge transistor 101 and the auxiliary discharge transistor 102 at this stage are less than accumulation capacity or accumulation speed of the electrostatic charges, voltage of the power supply VCC may continue to rise.

When voltage of the power supply VCC continues to rise, for example, voltage of the power supply VCC continues to rise from 1 V to 2 V, conduction capabilities or discharge speeds of the main discharge transistor 101 and the auxiliary discharge transistor 102 may become larger and larger, until the conduction capabilities or discharge speeds of the main discharge transistor 101 and the auxiliary discharge transistor 102 are equal to the accumulation capacity or accumulation speed of the electrostatic charges. At this point, voltage of the power supply VCC no longer continues to rise. For example, the voltage of the power supply VCC no longer rises beyond 2 V.

When voltage of the power supply VCC rises slowly, or when voltage of the power supply VCC no longer continues to rise, or when voltage of the power supply VCC starts to drop, charge (e.g., voltage) at the gate of the main discharge transistor 101 discharges through the monitoring resistor R1 (usually tens of kilohms), and voltage at node D1 gradually decreases to GND causing the main discharge transistor 101 to turn off. However, at this time, electrostatic charges on the first pad 201 may not completely discharged off. After voltage at node D1 drops to GND, voltage at node D2 may not be immediately pulled up to VCC, and the auxiliary discharge transistor 102 may continuously discharge remaining electrostatic charges, until voltage at node D2 is pulled up to VCC, at which point, the auxiliary discharge transistor 102 is turned off.

In the above-mentioned technical solution, the main discharge transistor 101 is directly driven by the monitoring capacitor C1, so that when an electrostatic pulse is detected, the main discharge transistor 101 quickly becomes conductive, to discharge electrostatic charges in a short time. However, when voltage at the first pad 201 no longer rises, voltage at node D1 is switched from a high level to a low level, and the main discharge transistor 101 is turned off. Because there is a time delay for the first driving transistor P1 of the first inverter 1041 to become conductive and voltage at node D2 to switch from a low level to a high level, the auxiliary discharge transistor 102 may continuously discharge remaining electrostatic charges, thereby prolonging a time to discharge the electrostatic charges and improving a discharge capacity of the electrostatic discharge protection circuit.

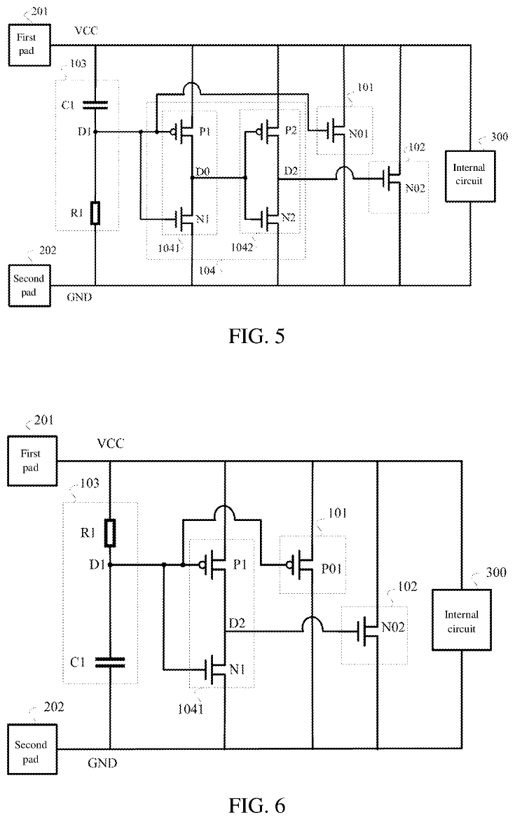

FIG. 5 illustrates a circuit diagram of an electrostatic discharge protection circuit of an internal circuit 300, according to an embodiment of this application. The schematic shown in FIG. 5 is similar to the schematic shown in FIG. 4. As shown in FIG. 5, in this embodiment, the main discharge transistor 101 and the auxiliary discharge transistor 102 are both N-type transistors. The monitoring unit 103 is same as the embodiment of FIG. 4 and will not be repeated herein.

The delay circuit 104 includes a first inverter 1041 and a second inverter 1042. The first inverter 1041 is provided with an input end and an output end and the second inverter 1042 is provided with an input end and an output end. The output end of the first inverter 1041 is connected or coupled to the input end of the second inverter 1042. The input end of the first inverter 1041 is the input end of the delay circuit 104 and the output end of the second inverter 1042 is the output end of the delay circuit 104.

The first inverter 1041 includes a first driving transistor P1 and a second driving transistor N1. The first driving transistor P1 is a P-type transistor, and the second driving transistor N1 is an N-type transistor. A source of the first driving transistor P1 is connected or coupled to the first pad 201, and a source of the second driving transistor N1 is connected or coupled to the second pad 202. A drain of the first driving transistor P1 is connected or coupled to a drain of the second driving transistor N1, and is the output end of the first inverter 1041. A gate of the first driving transistor P1 is connected or coupled to a gate of the second driving transistor N1, and is the input end of the first inverter 1041.

The second inverter 1042 includes a third driving transistor P2 and a fourth driving transistor N2. The third driving transistor P2 is a P-type transistor, and the fourth driving transistor N2 is an N-type transistor. A source of the third driving transistor P2 is connected or coupled to the first pad 201, and a source of the fourth driving transistor N2 is connected or coupled to the second pad 202. A drain of the third driving transistor P2 is connected or coupled to a drain of the fourth driving transistor N2, and is the output end of the second inverter 1042. A gate of the third driving transistor P2 is connected or coupled to a gate of the fourth driving transistor N2, and is the input end of the second inverter 1042.

The gate of the main discharge transistor 101 is connected or coupled to the second end of the monitoring capacitor C1. The gate of the first driving transistor P1 and the gate of the second driving transistor N1 are connected or coupled to the second end of the monitoring capacitor C1. The drain of the first driving transistor P1 and the drain of the second driving transistor N1 are connected or coupled to the gate of the third driving transistor P2. The drain of the third driving transistor P2 and the drain of the fourth driving transistor N2 are connected or coupled to the gate of the auxiliary discharge transistor 102.

In an embodiment, the auxiliary discharge transistor 102, the N-type transistor of the first inverter 1041, and the N-type transistor of the second inverter 1042 are all located in the same P-type well on a substrate. That is, the auxiliary discharge transistor 102, the second driving transistor N1, and the fourth driving transistor N2 are arranged in the same P-type well on the substrate. That is, the auxiliary discharge transistor 102 is configured to assist in bleeding electrostatic charges, a size of the auxiliary discharge transistor 102 may be relatively small, and the auxiliary discharge transistor 102, the second driving transistor N1, and the fourth driving transistor N2 are arranged in the same P-type well on the substrate, so as to arrange a layout of the electrostatic discharge protection circuit and reduce an area of the layout.

In an embodiment, the main discharge transistor 101 and the auxiliary discharge transistor 102 are located in different P-type wells on a substrate, the main discharge transistor 101 discharges most of electrostatic charges, the auxiliary discharge transistor 102 discharges a small portion of the electrostatic charges. As such, the main discharge transistor 101 has a discharge capacity that is higher than the auxiliary discharge transistor 102. The main discharge transistor 101 and the auxiliary discharge transistor 102 are arranged separately to avoid mutual influence between the main discharge transistor 101 and the auxiliary discharge transistor 102, thereby ensuring discharge current performance of the main discharge transistor 101 and the auxiliary discharge transistor 102.

In another embodiment, the main discharge transistor 101 and the auxiliary discharge transistor 102 are located in the same P-type well on a substrate, so as to arrange a layout of the electrostatic discharge protection circuit and reduce an area of the layout.

In an embodiment, a size of the main discharge transistor 101 and a size of the auxiliary discharge transistor 102 may be continuously optimized, so that the main discharge transistor 101 can be conductive to discharge most of electrostatic charges, and that the auxiliary discharge transistor 102 can remain conductive after the main discharge transistor 102 is turned off to continuously discharge the remaining electrostatic charges. For example, in one implementation, the size of the main discharge transistor 101 and the size of the auxiliary discharge transistor 102 are set to 10:1, 5:1, or 2:1.

The working principle of the electrostatic discharge protection circuit of FIG. 5 is described below with reference to FIG. 5:

When an electrostatic pulse is detected at the first pad 201, for example, when voltage of the power supply VCC rises from 0 V to 1 V in 1 ns, an impedance of the monitoring capacitor C1 drops due to high frequency of the electrostatic pulse. Voltage at node D1 is approximately at VCC, and the main discharge transistor 101 becomes conductive. The second driving transistor N1 also becomes conductive. After the second driving transistor N1 becomes conductive, voltage at node D0 is pulled down to GND and the third driving transistor P2 becomes conductive. At this time, voltage at node D2 is pulled up to VCC, and the auxiliary discharge transistor 102 becomes conductive after a delay due to conduction time associated with the second driving transistor N1 and the third driving transistor P1.

When voltage of the power supply VCC continues to rise, for example, when voltage of the power supply VCC continues to rise from 1 V to 2 V, conduction capabilities or discharge speeds of the main discharge transistor 101 and the auxiliary discharge transistor 102 may become larger and larger, until the conduction capabilities or discharge speeds of the main discharge transistor 101 and the auxiliary discharge transistor 102 are equal to accumulation speed of electrostatic charges, and voltage of the power supply VCC no longer continues to rise. For example, voltage of the power supply VCC no longer rises beyond 2 V.

When voltage of the power supply VCC rises slowly, or when voltage of the power supply VCC no longer continues to rise, or when voltage of the power supply VCC starts to drop, change (e.g., voltage) at the gate of the main discharge transistor 101 discharges through the monitoring resistor R1, and voltage at node D1 gradually decreases to GND, so that the main discharge transistor 101 is turned off. At this time, however, electrostatic charges on the first pad 201 may not be completely bled. After voltage at node D1 drops from VCC to GND, voltage at node D2 may not immediately drop from VCC to GND, but may be pulled down to GND after being delayed by conduction time of the first driving transistor P1 and the fourth driving transistor N2. As such, the auxiliary discharge transistor 102 may continuously discharge remaining electrostatic charges, until voltage at node D2 is pulled down to GND at which point the auxiliary discharge transistor 102 is turned off.

In the above-mentioned technical solution, when an electrostatic pulse is detected, the main discharge transistor 101 is first to conduct and the auxiliary discharge transistor 102 is second to conduct after a delay. In this way, the main discharge transistor 101 bleeds electrostatic charges first and is used as the main transistor for bleeding electrostatic charges. After a period of time, the main discharge transistor 101 is turned off, while the auxiliary discharge transistor 102 remains conductive due to a delay action of driving transistors, and continuously discharges remaining electrostatic charges, thereby prolonging a discharge time.

FIG. 6 illustrates a circuit diagram of an electrostatic discharge protection circuit of an internal circuit 300, according to an embodiment of this application. The schematic shown in FIG. 6 is similar to the schematic shown in FIG. 4. As shown in FIG. 6, the main discharge transistor 101 is a P-type transistor, the auxiliary discharge transistor 102 is an N-type transistor, and the monitoring unit 103 includes a monitoring resistor R1 and a monitoring capacitor C1. A first end of the monitoring resistor R1 is connected or coupled to the first pad 201, and a second end of the monitoring capacitor C1 is connected or coupled to the second pad 202. The first end of the monitoring capacitor C1 is connected or coupled to a second end of the monitoring resistor R1, and is the output end of the monitoring unit 103. Circuitry of the delay circuit 104 has been described in FIG. 4 and will not be repeated herein.

The working principle of the electrostatic discharge protection circuit of FIG. 6 is described below with reference to FIG. 6:

When an electrostatic pulse is detected at the first pad 201, for example, when voltage of the power supply VCC rises from 0 V to 1 V in 1 ns, an equivalent impedance of the monitoring capacitor C1 drops, voltage at node D1 is approximately at GND, and the main discharge transistor 101 becomes conductive. The first driving transistor P1 also becomes conductive. After the first driving transistor P1 becomes conductive, voltage at node D0 is pulled up to VCC after a delay of conduction time of the first driving transistor P1, and the auxiliary discharge transistor 102 becomes conductive.

When the electrostatic pulse continues to rise, for example, when voltage of the power supply VCC continues to rise from 1 V to 2 V, conduction capabilities or discharge speeds of the main discharge transistor 101 and the auxiliary discharge transistor 102 may become larger and larger, until the conduction capabilities or discharge speeds of the main discharge transistor 101 and the auxiliary discharge transistor 102 are equal to accumulation speeds of electrostatic charges, and voltage of the power supply VCC no longer continues to rise. For example, voltage of the power supply VCC no longer rises beyond 2 V.

When voltage of the power supply VCC rises slowly, or when voltage of the power supply VCC no longer continues to rise, or when voltage of the power supply VCC starts to drop, the gate of the main discharge transistor 101 charges to VCC through the monitoring resistor R1, and voltage at node D1 is pulled up to VCC, so that the main discharge transistor 101 is turned off, at which time, electrostatic charges on the first pad 201 are not completely bled. After voltage at node D1 is pulled up to VCC, voltage at node D2 may not immediately be pulled down to GND, but may be pulled down to GND after a delay by conduction time of the second driving transistor N1, and the auxiliary discharge transistor 102 may continuously discharge remaining electrostatic charges, until voltage at node D2 is pulled down to GND at which point the auxiliary discharge transistor 102 is turned off.

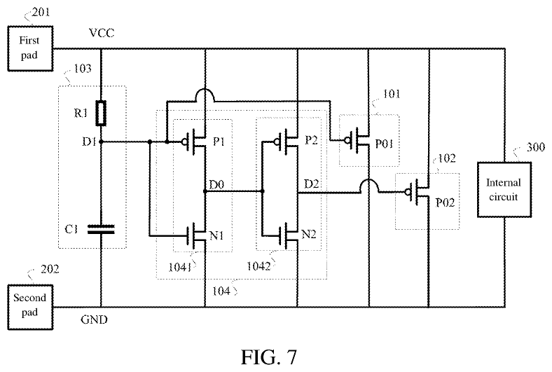

FIG. 7 illustrates a circuit diagram of an electrostatic discharge protection circuit of an internal circuit 300, according to an embodiment of this application. The schematic shown in FIG. 7 is similar to the schematic shown in FIG. 6. As shown in FIG. 7, the main discharge transistor 101 is a P-type transistor, the auxiliary discharge transistor 102 is also a P-type transistor, and the monitoring unit 103 includes a monitoring resistor R1 and a monitoring capacitor C1. A first end of the monitoring resistor R1 is connected to the first pad 201, and a second end of the monitoring capacitor C1 is connected to the second pad 202. A first end of the monitoring capacitor C1 is connected to a second end of the monitoring resistor R1, and is the output end of the monitoring unit 103. Circuitry of the delay circuit has been described in FIG. 5 and will not be repeated herein.

The working principle of the electrostatic discharge protection circuit of FIG. 7 is described below with reference to FIG. 7:

When an electrostatic pulse is detected, for example, when voltage of the power supply VCC rises from 0 V to 1 V in 1 ns, an impedance of the monitoring capacitor C1 drops, voltage at node D1 is approximately at GND, and the main discharge transistor 101 becomes conductive. The first driving transistor P1 also becomes conductive. After the first driving transistor P1 becomes conductive, voltage at node D0 is pulled up VCC, the fourth driving transistor N2 then becomes conductive. Voltage at node D2 is pulled down to GND, and the auxiliary discharge transistor 102 becomes conductive after a delay of conduction time of the first driving transistor P1 and the fourth driving transistor N2.

When the electrostatic pulse continues to rise, for example, when voltage of the power supply VCC continues to rise from 1 V to 2 V, conduction capabilities or discharge speeds of the main discharge transistor 101 and the auxiliary discharge transistor 102 may become larger and larger, until the conduction capabilities or discharge speeds of the main discharge transistor 101 and the auxiliary discharge transistor 102 are equal to accumulation speeds of electrostatic charges, and voltage of the power supply VCC no longer continues to rise. For example, voltage of the power supply VCC no longer rises beyond 2 V.

When voltage of the power supply VCC rises slowly, or when voltage of the power supply VCC no longer continues to rise, or when voltage of the power supply VCC starts to drop, at this time, an equivalent impedance of the monitoring capacitor C1 rises, the gate of the main discharge transistor 101 charges to VCC through the monitoring resistor R1, and voltage at node D1 is pulled up to VCC, so that the main discharge transistor 101 is turned off. However, electrostatic charges on the first pad 201 may not be completely bled. After voltage at node D1 is pulled to VCC, voltage at node D2 may not be immediately pulled up to VCC, but may be pulled up to VCC after being delayed by conduction time of the second driving transistor N1 and the third driving transistor P2, and the auxiliary discharge transistor 102 may continuously discharge remaining electrostatic charges, until voltage at node D2 is pulled up to VCC at which point the auxiliary discharge transistor P02 is turned off.

Other embodiments of this application will readily occur to those skilled in the art after considering the specification and practicing the invention disclosed herein. This application is intended to cover any variations, uses, or adaptations of this application that follow the general principles of this application and include common sense or conventional techniques in the art that are not disclosed herein. The specification and embodiments are to be considered exemplary only and the true scope and spirit of this application are indicated by the following claims.

It should be understood that this application is not limited to the precise structure already described above and shown in the accompanying drawings and various modifications and changes may be made without departing from its scope. The scope of this application is limited only by the appended claims.

What is claimed is:

1. An electrostatic discharge protection circuit disposed between a first pad and a second pad of a circuit comprising:
a main discharge transistor and an auxiliary discharge transistor, both configured to be conductive after an electrostatic pulse caused by electrostatic charges is detected on the first pad to discharge the electrostatic charges to the second pad, wherein:
conduction time of the main discharge transistor is prior to conduction time of the auxiliary discharge transistor; and
an amount of the electrostatic charges discharged by the main discharge transistor is greater than an amount of the electrostatic charges discharged by the auxiliary discharge transistor.

2. The electrostatic discharge protection circuit according to claim 1, further comprising:
a monitoring unit, configured to monitor the electrostatic pulse caused by the electrostatic charges, wherein an output end of the monitoring unit is connected to a control end of the main discharge transistor.

3. The electrostatic discharge protection circuit according to claim 2, wherein the monitoring unit comprises:
a monitoring capacitor, wherein a first end of the monitoring capacitor is connected to the first pad; and
a monitoring resistor, wherein a first end of the monitoring resistor is connected to a second end of the monitoring capacitor and a second end of the monitoring resistor is connected to the second pad.

4. The electrostatic discharge protection circuit according to claim 2, further comprising:
a delay circuit, wherein an input end of the delay circuit is connected to the control end of the main discharge transistor and an output end of the delay circuit is connected to a control end of the auxiliary discharge transistor.

5. The electrostatic discharge protection circuit according to claim 4, wherein the delay circuit comprises:
a first inverter, wherein an input end of the first inverter is the input end of the delay circuit and an output end of the first inverter is the output end of the delay circuit.

6. The electrostatic discharge protection circuit according to claim 5, wherein the main discharge transistor is an N-type transistor and the auxiliary discharge transistor is a P-type transistor.

7. The electrostatic discharge protection circuit according to claim 5, wherein the auxiliary discharge transistor and a P-type transistor of the first inverter are arranged in a same N-type well on a substrate.

8. The electrostatic discharge protection circuit according to claim 5, wherein the auxiliary discharge transistor and a P-type transistor of the first inverter are located in different N-type wells on a substrate.

9. The electrostatic discharge protection circuit according to claim 5, wherein the delay circuit further comprises:
a second inverter, wherein an input end of the second inverter is connected to an output end of the first inverter, and an output end of the second inverter is the output end of the delay circuit.

10. The electrostatic discharge protection circuit according to claim 9, wherein the main discharge transistor is an N-type transistor; and the auxiliary discharge transistor is an N-type transistor.

11. The electrostatic discharge protection circuit according to claim 9, wherein:
the auxiliary discharge transistor, an N-type transistor of the first inverter, and an N-type transistor of the second inverter are all located in a same P-type well on a substrate; and
the main discharge transistor and the auxiliary discharge transistor are located in different P-type wells on the substrate.

12. The electrostatic discharge protection circuit according to claim 9, wherein the main discharge transistor and the auxiliary discharge transistor are located in a same P-type well on a substrate.

13. The electrostatic discharge protection circuit according to claim 2, wherein the monitoring unit comprises:
a monitoring resistor, wherein a first end of the monitoring resistor is connected to the first pad; and
a monitoring capacitor, wherein a first end of the monitoring capacitor is connected to a second end of the monitoring resistor, and a second end of the monitoring capacitor is connected to the second pad.

14. The electrostatic discharge protection circuit according to claim 13, wherein the main discharge transistor is a P-type transistor.

15. The electrostatic discharge protection circuit according to claim 1, wherein a size of the main discharge transistor is greater than a size of the auxiliary discharge transistor.
